(19) United States
(12) Patent Application Publication
(10) Pub. No.: US 2026/0362626 A1
(43) Pub. Date: Nov. 12, 2026

(54) SERVER RACK WITH INTEGRATED AC WHIP ROUTING

(71) Applicant: Dell Products L.P., Round Rock, TX (US)

(72) Inventor: Douglas Evan Messick, Austin, TX (US)

(21) Appl. No.: 19/199,780

(22) Filed: May 6, 2025

(51) Int. Cl. H05K 7/14; H05K 5/02

(52) U.S. Cl. CPC H05K 7/1492; H05K 5/023

(57) ABSTRACT

A server rack including a first end and second end that is opposite to the first end, a front surface and a rear surface that is opposite to the front surface, the front and the rear surfaces extending between the first and the second ends, including an outer frame including a first member; an inner frame, including: a first member; a second member transverse to the first member; a hallway support positioned between the second member of the inner frame and the first member of the outer frame and extending between the front surface and the rear surface of the server rack; a baffle extending from the first end to the second end of the server rack, the baffle including: a first member including second apertures; a second member transverse to the first member; and a third member transverse to the second member and parallel to the first member.

### BACKGROUND

### Field of the Disclosure

The disclosure relates generally to a server rack, and in particular, a server rack with integrated AC whip routing.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Server racks are essential for organizing and housing multiple servers and networking equipment in a data center. They provide efficient cooling and cable management, ensuring optimal performance and easy maintenance. Typically, server racks come in standard sizes, such as 19-inch width, to accommodate various hardware components. Additionally, they enhance security by allowing physical access control to the servers and other critical equipment.

### SUMMARY

Innovative aspects of the subject matter described in this specification may be embodied in a server rack including a first end and second end that is opposite to the first end, a front surface and a rear surface that is opposite to the front surface, the front and the rear surfaces extending between the first and the second ends, the server rack including an outer frame including a first member; an inner frame, including: a first member including first apertures; a second member transverse to the first member, wherein a hallway is defined between the second member of the inner frame and the first member of the outer frame; a hallway support positioned between the second member of the inner frame and the first member of the outer frame and extending between the front surface and the rear surface of the server rack; a baffle extending from the first end to the second end of the server rack, the baffle including: a first member including second apertures; a second member transverse to the first member; and a third member transverse to the second member and parallel to the first member; wherein fasteners couple the baffle to the inner frame through the second apertures of the first member of the baffle and through the first apertures of the first member of the inner frame, wherein the second member of the baffle is proximate to the second member of the inner frame, wherein the third member extends between the second member of the inner frame and the first member of the outer frame such that the third member of the baffle is positioned within the hallway and configured to prevent airflow within the hallway.

Other embodiments of these aspects include corresponding systems and apparatus.

These and other embodiments may each optionally include one or more of the following features. For instance, further including AC whips, wherein the baffle and the first member of the outer frame define a routing channel extending from the first end to the second end of the server rack, wherein the AC whips are positioned within the routing channel. The baffle further includes a fourth member transverse to the third member of the baffle, wherein the fourth member of the baffle is parallel to the second member of the baffle. The third member of the baffle extends linearly between the second member of the inner frame and the first member of the outer frame within the hallway. The third member is transverse to the second member of the inner frame and transverse to the first member of the outer frame. The hallway support extends linearly between the second member of the inner frame and the first member of the outer frame within the hallway. The third member of the baffle is arched between the second member of the inner frame and the first member of the outer frame within the hallway. The hallway support is arched between the second member of the inner frame and the first member of the outer frame within the hallway.

Particular implementations of the subject matter described in this specification can be implemented so as to realize one or more of the following advantages. For example, enhanced vertical AC whip routing volume and a much larger routing channel significantly improve the in-rack routing of AC whips. This enhancement allows the rack to accommodate rear-mounted IT gear, such as a rear door heat exchanger (RDHx) or heat capture cabinet (HCC). Since all volume in the rack is valuable, these changes unlock a significant amount of volume in a crucial location.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a front perspective view of a server rack.

FIG. 3 illustrates a back perspective view of the server rack.

FIG. 4 illustrates a back view of the server rack.

FIG. 5 illustrates a top down view of the server rack.

FIG. 6 illustrates a top down view of a portion of the server rack.

FIG. 7 illustrates a top down perspective view of a portion of the server rack.

FIG. 8 illustrates a top down perspective view of a portion of the server rack, in a further implementation.

### DESCRIPTION OF PARTICULAR EMBODIMENT(S)

This disclosure discusses a server rack. In short, creating a routing channel for AC whips in the rear corners of the server rack involves making specific changes to the rear corners, adding supports for the outer rack side panels, and adjusting the width of the center removable panel. These modifications result in a significantly larger AC whip routing channel in the space where the AC whips can be routed. Additionally, unlocking volume within the rear corners of the rack increases AC whip cable routing capacity. Positioning the rear baffle in a more forward location within the rack further enhances AC whip cable routing.

Specifically, this disclosure discusses a server rack including a first end and second end that is opposite to the first end, a front surface and a rear surface that is opposite to the front surface, the front and the rear surfaces extending between the first and the second ends, the server rack including: an outer frame including a first member; an inner frame, including: a first member including first apertures; a second member transverse to the first member, wherein a hallway is defined between the second member of the inner frame and the first member of the outer frame; a hallway support positioned between the second member of the inner frame and the first member of the outer frame and extending between the front surface and the rear surface of the server rack; a baffle extending from the first end to the second end of the server rack, the baffle including: a first member including second apertures; a second member transverse to the first member; and a third member transverse to the second member and parallel to the first member; wherein fasteners couple the baffle to the inner frame through the second apertures of the first member of the baffle and through the first apertures of the first member of the inner frame, wherein the second member of the baffle is proximate to the second member of the inner frame, wherein the third member extends between the second member of the inner frame and the first member of the outer frame such that the third member of the baffle is positioned within the hallway and configured to prevent airflow within the hallway.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

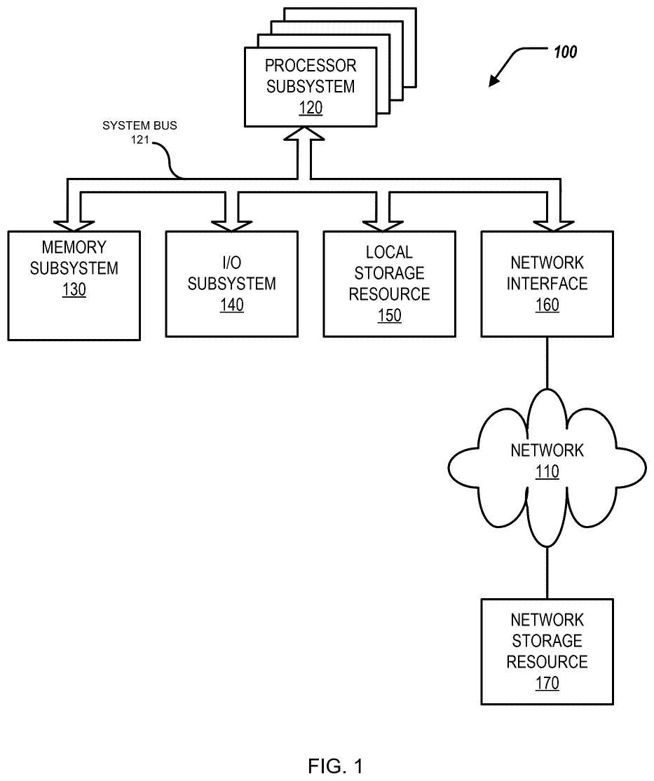

Particular embodiments are best understood by reference to FIGS. 1-8 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

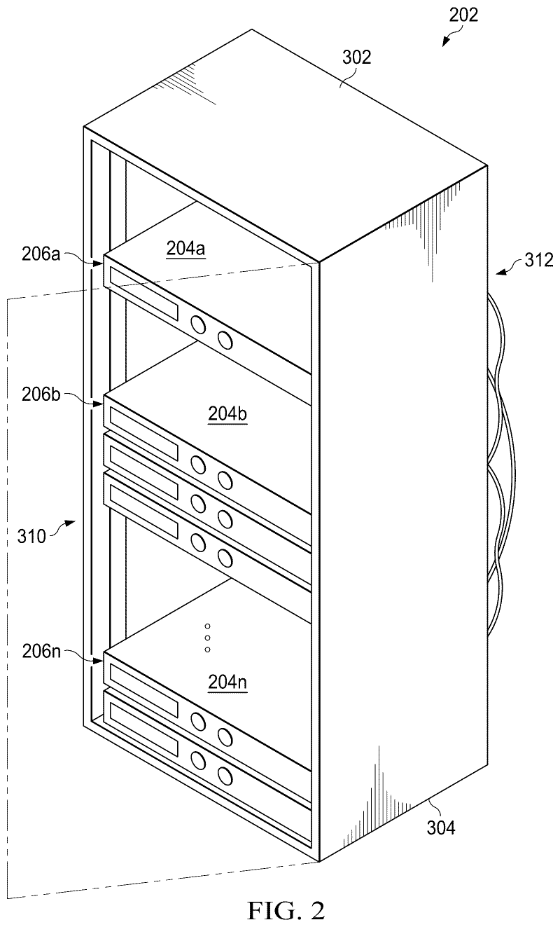

Turning to FIG. 2, FIG. 2 illustrates a perspective front view of a server rack 202. The server rack 202 can include rack units 204a, 204b, . . . , 204n (collectively referred to as rack units 204); and servers 206a, 206b, . . . , 206n (collectively referred as servers 206). The servers 206 can be similar to, or include, the information handling system 100 of FIG. 1. The servers 206 can be (physically) coupled to respective rack units 204.

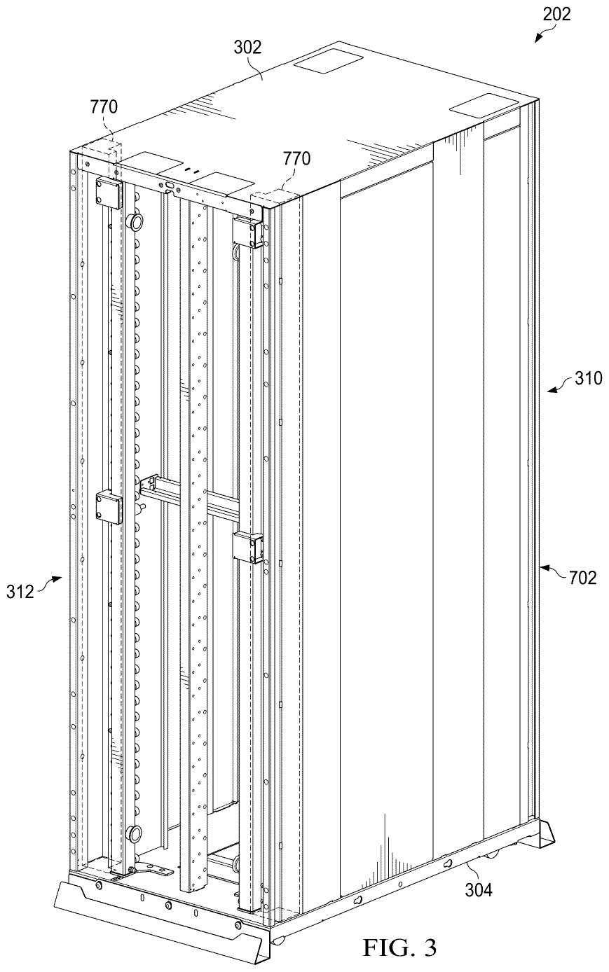

FIG. 3 illustrates a perspective back view of the server rack 202. The server rack 202 can include a first end 302 and a second end 304. The second end 304 is opposite to the first end 302. The server rack 202 can further include a front surface 310 and a rear surface 312. The rear surface 312 is opposite to the front surface 310. The front surface 310 and the rear surface 312 extend between the first end 302 and the second end 304.

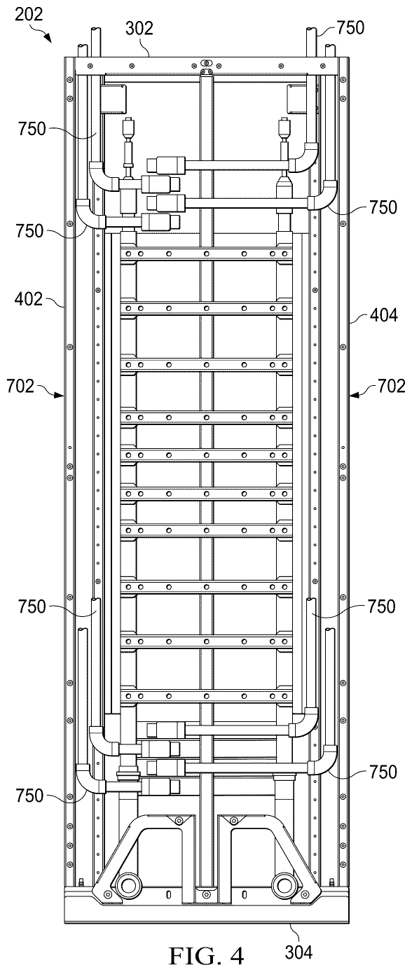

FIG. 4 illustrates a back view of the server rack 202. The server rack 202 can further include a first side surface 402 and a second side surface 404. The second side surface 404 is opposite to the first side surface 402. The first side surface 402 and the second side surface 404 extend between the first end 302 and the second end 304.

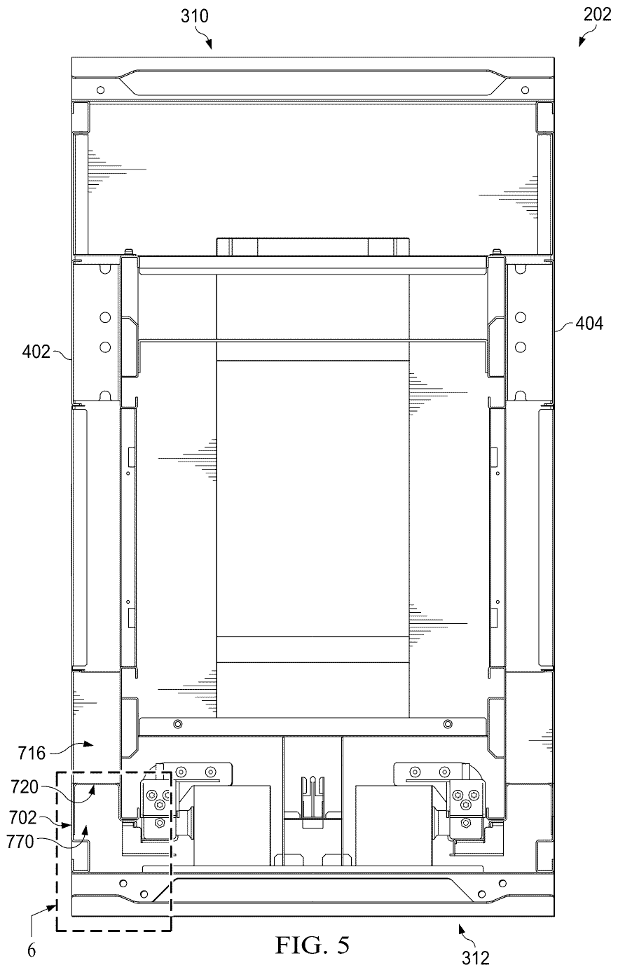

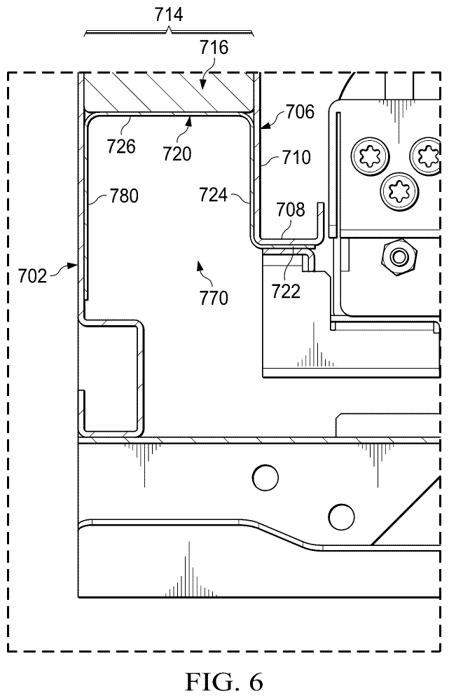

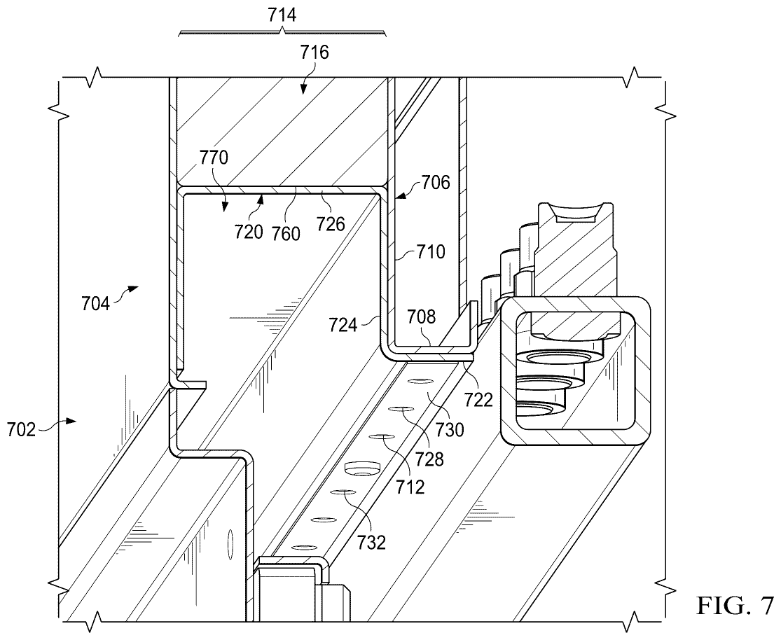

FIG. 5 illustrates a top down view of the server rack 202. FIG. 6 illustrates a top down view of a portion of the server rack 202. FIG. 7 illustrates a perspective view of a portion of the server rack 202.

In short, creating a routing channel for AC whips in the rear corners of the server rack involves making specific changes to the rear corners, adding supports for the outer rack side panels, and adjusting the width of the center removable panel. These modifications result in a significantly larger AC whip routing channel in the space where the AC whips can be routed. Additionally, unlocking volume within the rear corners of the rack increases AC whip cable routing capacity. Positioning the rear baffle in a more forward location within the rack further enhances AC whip cable routing.

Referring to FIGS. 2-7, the server rack 202 includes an outer frame 702. The outer frame 702 can include a first member 704. The server rack 202 can further include an inner frame 706. The inner frame 706 can include a first member 708 and a second member 710. The second member 710 can be transverse to the first member 708. The first member 708 can include first apertures 712. A hallway 714 can be defined between the second member 710 of the inner frame 706 and the first member 704 of the outer frame 702. The server rack 202 can further include a hallway support 716. The hallway support 716 can be positioned between the second member 710 of the inner frame 706 and the first member 704 of the outer frame 702. Further, the hallway support 716 can extend at least partially between the front surface 310 and the rear surface 312 of the server rack 202. The hallway support 716 can help maintain the hallway 714 (e.g., structural integrity of the hallway 714).

The server rack 202 can further include a baffle 720. The baffle 720 can extend from the first end 302 of the server rack 202 to the second end 304 of the server rack 204. The baffle 720 can include a first member 722, a second member 724, and a third member 726. The second member 724 can be transverse to the first member 722. The first member 722 can further include second apertures 728.

The server rack 202 can further include fasteners (not shown) that couple the baffle 720 to the inner frame 706. The fasteners can couple the baffle 720 to the inner frame 706 through the second apertures 728 of the first member 722 of the baffle 720 and through the first apertures 712 of the first member 704 of the inner frame 706.

In some examples, the server rack 202 further includes a coupling strip 730. The coupling strip 730 can include third apertures 732. The coupling strip 730 can facilitate coupling the baffle 720 to the inner frame 706. Specifically, the fasteners can couple the baffle 720 to the inner frame 706 through the third apertures 732 of the coupling strip 730, through the second apertures 728 of the first member 722 of the baffle 720 and through the first apertures 712 of the first member 704 of the inner frame 706.

The server rack 202 can further include AC (alternating current) whips 750.

To that end, the second member 724 of the baffle 720 is proximate to the second member 710 of the inner frame 706. In some examples, the second member 724 of the baffle 720 is proximate to the second member 710 of the inner frame 706 without being coupled to the second member 710 of the inner frame 706. In some examples, the second member 724 of the baffle 720 touches the second member 710 of the inner frame 706. In some examples, the second member 724 of the baffle 720 is proximate to the second member 710 of the inner frame 706 such that a small gap exists there between. In some examples, the second member 724 of the baffle 720 is coupled to the second member 710 of the inner frame 706 (e.g., via fasteners or adhesive).

Furthermore, the third member 726 of the baffle 720 extends between the second member 710 of the inner frame 706 and the first member 704 of the outer frame 702. The third member 726 of the baffle 720 extends between the second member 710 of the inner frame 706 and the first member 704 of the outer frame 702 such that the third member 726 of the baffle 720 is positioned within the hallway 714 and configured to prevent airflow within the hallway 714. That is, the baffle 720 serves as a physical barrier to airflow within the hallway 714 (e.g., from a fan).

In some examples, the third member 726 of the baffle 720 extends linearly between the second member 710 of the inner frame 706 and the first member 704 of the outer frame 702 within the hallway 714. That is, the third member 726 of the baffle 720 is transverse to the second member 724 and parallel to the first member 722. The third member 726 can be spaced-apart from the first member 722 (i.e., by the second member 724). Further, the third member 726 of the baffle 720 is transverse to the second member 710 of the inner frame 706; and transverse to the first member 704 of the outer frame 702. Moreover, the hallway support 716 extends linearly between the second member 710 of the inner frame 706 and the first member 704 of the outer frame 702 within the hallway 714. That is, an edge surface 760 of the hallway support 716 extends linearly between the second member 710 of the inner frame 706 and the first member 704 of the outer frame 702 within the hallway 714.

In some examples, the third member 726 of the baffle 720 is proximate to the edge surface 760 of the hallway support 716 without being coupled to the edge surface 760 of the hallway support 716. In some examples, the third member 726 of the baffle 720 touches the edge surface 760 of the hallway support 716. In some examples, the third member 726 of the baffle 720 is proximate to the edge surface 760 of the hallway support 716 such that a small gap exists there between. In some examples, the third member 726 of the baffle 720 is coupled to the edge surface 760 of the hallway support 716 (e.g., via fasteners or adhesive).

To that end, the baffle 720 and the first member 704 of the outer frame 702 define a routing channel 770. The routing channel 770 extends from the first end 302 of the server rack 202 to the second end 304 of the server rack 202. The AC whips 750 are positioned within the routing channel 770. That is, the AC whips 750 are substantially contained within the routing channel 770. That is, the AC whips 750 can be coupled to one or more components of the server rack 202 (such as the servers 206) and positioned within the routing channel 770 such that the AC whips 750 are substantially contained within the routing channel 770. That is, along the rear surface 312, the AC whips 750 are substantially contained within the routing channel 770. That is, there is minimal extrusion of the AC whips 750 along the rear surface 312 of the server rack 202.

In some further implementations, the baffle 720 further includes a fourth member 780, as shown in FIG. 6. The fourth member 780 is transverse to the third member 726. The fourth member 780 is parallel to the second member 724. The fourth member 780 is spaced-apart from the second member 724 by the third member 726.

In some examples, the fourth member 780 of the baffle 720 is proximate to the first member 704 of the outer frame 702 without being coupled to the first member 704 of the outer frame 702. In some examples, the fourth member 780 of the baffle 720 touches the first member 704 of the outer frame 702. In some examples, the fourth member 780 of the baffle 720 is proximate to the first member 704 of the outer frame 702 such that a small gap exists there between. In some examples, the fourth member 780 of the baffle 720 is coupled to the first member 704 of the outer frame 702 (e.g., via fasteners or adhesive).

In some examples, when the baffle 720 includes the fourth member 780, the fourth member 780 constitutes the outer frame 702. That is, the fourth member 780 replaces the outer frame 702 and serves as the outer frame 702 at that particular interface.

In some examples, the baffle 720 excludes the fourth member 780.

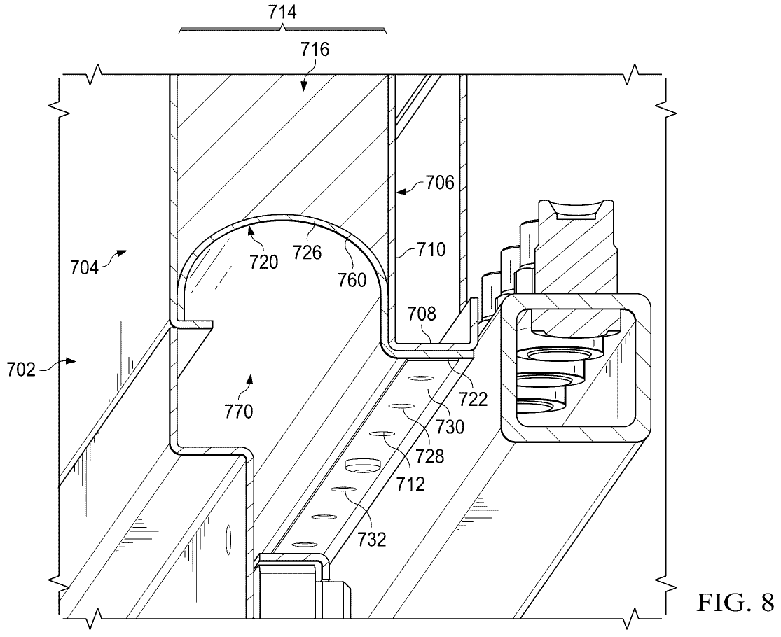

FIG. 8 illustrates a further example of the baffle 720. In some examples, the third member 726 of the baffle 720 is arched between the second member 710 of the inner frame 706 and the first member 704 of the outer frame 702 within the hallway 714.

Moreover, the hallway support 716 is arched between the second member 710 of the inner frame 706 and the first member 704 of the outer frame 702 within the hallway 714. That is, the edge surface 760 of the hallway support 716 is arched between the second member 710 of the inner frame 706 and the first member 704 of the outer frame 702 within the hallway 714. In some examples, the arch of the second member 710 is substantially the same as the arch of the edge surface 760 of the hallway support 716. In some examples, the arch of the second member 710 differs from the arch of the edge surface 760 of the hallway support 716 (smaller or larger arch).

In some examples, the third member 726 of the baffle 720 is proximate to the edge surface 760 of the hallway support 716 without being coupled to the edge surface 760 of the hallway support 716. In some examples, the third member 726 of the baffle 720 touches the edge surface 760 of the hallway support 716. In some examples, the third member 726 of the baffle 720 is proximate to the edge surface 760 of the hallway support 716 such that a small gap exists there between. In some examples, the third member 726 of the baffle 720 is coupled to the edge surface 760 of the hallway support 716 (e.g., via fasteners or adhesive).

Furthermore, the baffle 720 and the routing channel 770, as discussed herein, can be implemented along the first side surface 402, the second side surface 404, or both.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

1. A server rack including a first end and second end that is opposite to the first end, a front surface and a rear surface that is opposite to the front surface, the front and the rear surfaces extending between the first and the second ends, the server rack including:
an outer frame including a first member;
an inner frame, including:
a first member including first apertures;
a second member transverse to the first member of the inner frame, wherein a hallway is defined between the second member of the inner frame and the first member of the outer frame;
a hallway support positioned between the second member of the inner frame and the first member of the outer frame and extending between the front surface and the rear surface of the server rack;
a baffle extending from the first end to the second end of the server rack, the baffle including:
a first member including second apertures;
a second member transverse to the first member of the baffle; and
a third member transverse to the second member of the baffle and parallel to the first member of the baffle;
wherein fasteners couple the baffle to the inner frame through the second apertures of the first member of the baffle and through the first apertures of the first member of the inner frame,
wherein the second member of the baffle is proximate to the second member of the inner frame,
wherein the third member extends between the second member of the inner frame and the first member of the outer frame such that the third member of the baffle is positioned within the hallway and configured to prevent airflow within the hallway.

2. The server rack of claim 1,
further including AC whips,
wherein the baffle and the first member of the outer frame define a routing channel extending from the first end to the second end of the server rack,
wherein the AC whips are positioned within the routing channel.

3. The server rack of claim 1,
wherein the baffle further includes a fourth member transverse to the third member of the baffle,
wherein the fourth member of the baffle is parallel to the second member of the baffle.

4. The server rack of claim 1, wherein the third member of the baffle extends linearly between the second member of the inner frame and the first member of the outer frame within the hallway.

5. The server rack of claim 4, wherein the third member is transverse to the second member of the inner frame and transverse to the first member of the outer frame.

6. The server rack of claim 5, wherein the hallway support extends linearly between the second member of the inner frame and the first member of the outer frame within the hallway.

7. The server rack of claim 1, wherein the third member of the baffle is arched between the second member of the inner frame and the first member of the outer frame within the hallway.

8. The server rack of claim 7, wherein the hallway support is arched between the second member of the inner frame and the first member of the outer frame within the hallway.

9. A server rack including a first end and second end that is opposite to the first end, a front surface and a rear surface that is opposite to the front surface, the front and the rear surfaces extending between the first and the second ends, the server rack including:
AC whips
an outer frame including a first member;
an inner frame, including:
a first member;
a second member transverse to the first member of the inner frame;
a hallway support positioned between the second member of the inner frame and the first member of the outer frame and extending between the front surface and the rear surface of the server rack;
a baffle extending from the first end to the second end of the server rack, the baffle including:
a first member including second apertures;
a second member transverse to the first member of the baffle; and
a third member transverse to the second member of the baffle and parallel to the first member of the baffle;
wherein the baffle is coupled to the inner frame, wherein the second member of the baffle is proximate to the second member of the inner frame,
wherein the third member extends between the second member of the inner frame and the first member of the outer frame such that the third member of the baffle is positioned within the hallway,
wherein the baffle and the first member of the outer frame define a routing channel extending from the first end to the second end of the server rack,
wherein the AC whips are positioned within the routing channel.

10. (canceled)

11. The server rack of claim 9,
wherein the baffle further includes a fourth member transverse to the third member of the baffle,
wherein the fourth member of the baffle is parallel to the second member of the baffle.

12. The server rack of claim 9, wherein the third member of the baffle extends linearly between the second member of the inner frame and the first member of the outer frame.

13. The server rack of claim 12, wherein the third member is transverse to the second member of the inner frame and transverse to the first member of the outer frame.

14. The server rack of claim 13, wherein the hallway support extends linearly between the second member of the inner frame and the first member of the outer frame.

15. The server rack of claim 9, wherein the third member of the baffle is arched between the second member of the inner frame and the first member of the outer frame.

16. The server rack of claim 15, wherein the hallway support is arched between the second member of the inner frame and the first member of the outer frame.

17. A server rack including a first end and second end that is opposite to the first end, a front surface and a rear surface that is opposite to the front surface, the front and the rear surfaces extending between the first and the second ends, the server rack including:
AC whips;
an outer frame including a first member;
an inner frame, including:
a first member including first apertures;
a second member transverse to the first member of the inner frame, wherein a hallway is defined between the second member of the inner frame and the first member of the outer frame;
a hallway support positioned between the second member of the inner frame and the first member of the outer frame and extending between the front surface and the rear surface of the server rack;
a baffle extending from the first end to the second end of the server rack, the baffle including:
a first member including second apertures;
a second member transverse to the first member of the baffle; and
a third member transverse to the second member of the baffle and parallel to the first member of the baffle;
wherein fasteners couple the baffle to the inner frame through the second apertures of the first member of the baffle and through the first apertures of the first member of the inner frame,
wherein the second member of the baffle is proximate to the second member of the inner frame,
wherein the third member extends between the second member of the inner frame and the first member of the outer frame such that the third member of the baffle is positioned within the hallway and configured to prevent airflow within the hallway,
wherein the baffle and the first member of the outer frame define a routing channel extending between the first end to the second end of the server rack,
wherein the AC whips are positioned within the routing channel.

18. The server rack of claim 17,
wherein the baffle further includes a fourth member transverse to the third member of the baffle,
wherein the fourth member of the baffle is parallel to the second member of the baffle.

19. The server rack of claim 17, wherein the third member of the baffle extends linearly between the second member of the inner frame and the first member of the outer frame within the hallway.

20. The server rack of claim 19, wherein the third member is transverse to the second member of the inner frame and transverse to the first member of the outer frame.
